(19) United States
(12) Patent Application Publication
(10) Pub. No.: US 2021/0351045 A1
(43) Pub. Date: Nov. 11, 2021

(54) RESIN MOLDING APPARATUS AND CLEANING METHOD

(71) Applicant: APIC YAMADA CORPORATION, Nagano (JP)

(72) Inventors: Masahiko FUJISAWA, Nagano (JP); Hirofumi SAITO, Nagano (JP)

(73) Assignee: APIC YAMADA CORPORATION, Nagano (JP)

(21) Appl. No.: 17/189,286

(22) Filed: Mar. 2, 2021

(30) Foreign Application Priority Data
May 11, 2020 (JP) 2020-083368

(51) Int. Cl. H01L 21/67; B29C 43/18; B29C 43/36; B29C 43/52; B08B 1/00; B08B 1/02; B08B 5/04; A46B 13/02; A46B 15/00; B29C 31/00

(52) U.S. Cl. CPC H01L 21/67028; B29L 2031/34; H01L 21/67092; B29C 43/18; B29C 43/36; B29C 43/52; B08B 1/002; B08B 1/02; B08B 5/043; A46B 13/02; A46B 15/0053; B29C 31/008; H01L 21/67161; H01L 21/67236; H01L 21/6715

(57) ABSTRACT

A resin molding apparatus and a cleaning method of a workpiece which can prevent a workpiece from being carried into a mold die in a state where particles (dust) are adhered to the workpiece, and can prevent deterioration of molding quality. A resin molding apparatus according to the present invention, in which a workpiece with an electronic component mounted on a carrier and a mold resin are carried into a mold die, includes: a press part having the mold die for clamping and resin-sealing the workpiece and the mold resin; and a cleaning apparatus for cleaning a back surface of the workpiece conveyed to the press part, wherein the electronic component is not mounted on the back surface. The cleaning apparatus is arranged at a position overlapping a conveyance path of the workpiece on the upstream side of the press part.

### CROSS-REFERENCE TO RELATED APPLICATION

This application claims the priority benefit of Japan application serial no. 2020-083368, filed on May 11, 2020. The entirety of the above-mentioned patent application is hereby incorporated by reference herein and made a part of this specification.

### BACKGROUND

### Technical Field

The present invention relates to a resin molding apparatus that molds a workpiece and a cleaning method of a workpiece.

### Related Art

When a workpiece with an electronic component mounted on a carrier is molded, a resin molding apparatus that melt-hardens and molds a mold resin is used.

The resin molding apparatus supplies a predetermined amount of mold resin to a mold region (cavity) arranged in a mold die configured by an upper die and a lower die, and arranges, for example, a workpiece in the mold region and resin-seals the workpiece by an operation of clamping the workpiece by the upper die and the lower die. There are many types of resin molding apparatuses including a transfer molding apparatus that forcibly feeds the resin put into a pot, and a compression molding apparatus that puts a workpiece and resin into a mold die and reduces the volume of a cavity to obtain a required shape. Furthermore, the compression molding apparatus includes a lower die cavity movable compression molding apparatus having a movable cavity arranged in a lower die, and an upper die cavity movable compression molding apparatus having a movable cavity arranged in an upper die. At this time, when a compression molding die having a movable cavity arranged in an upper die is used, for example, a workpiece is carried into the compression molding die and molded, and in this workpiece, a mold resin is supplied onto a carrier on which an electronic component such as a semiconductor chip or the like is mounted (see Patent literature 1: Japanese Patent Laid-Open No. 2015-128908). Further, when a compression molding die having a movable cavity arranged in a lower die is used, for example, a mold resin is supplied onto a film supported by a support tool, the film and the mold resin are carried into the lower die together with the support tool, and on the other hand, a workpiece including a carrier is carried into the upper die and molded (see Patent literature 2: Japanese Patent Laid-Open No. 2004-148621).

As described above, in the compression molding apparatus having a mold die in which a movable cavity is arranged in the upper die, because the supplied mold resin, especially a granular resin or a powdery resin is conveyed while being placed on the workpiece, contamination (pollution, foreign matter mixing) caused by particles (dust such as resin powder, foreign matter and the like) is likely to occur in the apparatus. Further, in the compression molding apparatus using a mold die in which a movable cavity is arranged in the lower die, because the mold resin, especially the granule resin or the powdery resin is conveyed while being placed on the film supported by the support tool, contamination caused by particles is likely to occur in the apparatus as well. Especially in the case of the compression molding apparatus, as for the number of semiconductor chips mounted on the workpiece, there are some locations where the semiconductor chip is not mounted on the workpiece for some reason in a previous process, and the amount of resin at one time of molding cannot be made constant. Therefore, a liquid resin, the granular resin and the powdery resin are adopted because the amount of resin required for molding must be easily changed. In particular, when the granule resin or the powder resin is used, contamination caused by particles occurs. In addition, in the case of transfer molding, a tablet-shaped solid resin is used, but a part may be lost because of a state in which the powdery resin is solidified. Furthermore, dust is generated due to rubbing between the tablet resins during resin conveyance. Therefore, if particles adhere to the workpiece carried into the mold die, contamination occurs in a molded product, and if particles get into a space between the upper and lower dies, the flatness of a molded product is impaired and a variation arises in total thickness variation (TTV), thus causing deterioration of molding quality.

The present invention provides a resin molding apparatus and a cleaning method of a workpiece, which can prevent a workpiece from being carried into a mold die in a state where particles (dust) are adhered to the workpiece, and can prevent deterioration of molding quality.

### SUMMARY

A resin molding apparatus according to the present invention, in which a workpiece with an electronic component mounted on a carrier and a mold resin are carried into a mold die, includes: a press part having the mold die for clamping and resin-sealing the workpiece and the mold resin; and a cleaning apparatus for cleaning a back surface of the workpiece conveyed to the press part, wherein the electronic component is not mounted on the back surface; and the cleaning apparatus is arranged at a position overlapping a conveyance path of the workpiece on the upstream side of the press part.

Further, as another aspect of the present invention, a resin molding apparatus according to the present invention, in which a workpiece with an electronic component mounted on a carrier and a mold resin are carried into a mold die, includes: a press part having the mold die for clamping and resin-sealing the workpiece and the mold resin; and a cleaning apparatus for sucking a front surface of the workpiece conveyed to the press part, wherein the electronic component is mounted on the front surface; and the cleaning apparatus is arranged at a position overlapping a conveyance path of the workpiece on the upstream side of the press part.

Further, as another aspect of the present invention, a resin molding apparatus according to the present invention includes a mold die for compressing and molding a workpiece with an electronic component mounted on a carrier and a mold resin, and the workpiece and the mold resin are separately carried into the mold die; wherein a cleaning apparatus is included at a position after the mold resin is supplied to a resin mold conveying tool that carries the mold resin into the mold die, and the cleaning apparatus has a suction part that sucks dust floating in the resin molding apparatus.

Further, a cleaning method according to the present invention is a cleaning method of a workpiece with an electronic component mounted on a carrier, wherein a cleaning apparatus that comes into contact with the workpiece is arranged at a position overlapping a conveyance path of the workpiece, and the workpiece and the cleaning apparatus are relatively moved to clean a back surface of the workpiece on which the electronic component is not mounted.

### BRIEF DESCRIPTION OF THE DRAWINGS

FIG. 1 is an apparatus configuration diagram showing an example of a resin molding apparatus according to an embodiment of the present invention.

FIG. 2 is a schematic diagram (front cross-section view, cross-section view taken along II-II line of FIG. 4) showing a configuration example of a cleaning apparatus according to the embodiment of the present invention.

FIG. 3(a) and FIG. 3(b) are schematic diagrams (plan view) showing the configuration example of the cleaning apparatus according to the embodiment of the present invention.

FIG. 4 is a schematic diagram (left side view) showing the configuration example of the cleaning apparatus according to the embodiment of the present invention.

FIG. 5(a) and FIG. 5(b) are explanatory diagrams showing an example in which the cleaning apparatus according to the embodiment of the present invention is applied to clean a back surface of a workpiece on which an electronic component is not mounted in a compression molding apparatus having a movable cavity in an upper die.

FIG. 6 is an explanatory diagram showing an example in which the cleaning apparatus according to the embodiment of the present invention is applied to a compression molding apparatus having a movable cavity in a lower die.

FIG. 7 is an explanatory diagram showing an example in which the cleaning apparatus according to the embodiment of the present invention is applied to clean a front surface of a workpiece on which an electronic component is mounted.

FIG. 8 is an explanatory diagram showing another example of a brush body of the cleaning apparatus according to the embodiment of the present invention.

### DESCRIPTION OF THE EMBODIMENTS

A resin molding apparatus according to the present invention, in which a workpiece with an electronic component mounted on a carrier and a mold resin are carried into a mold die, includes: a press part having the mold die for clamping and resin-sealing the workpiece and the mold resin; and a cleaning apparatus for cleaning a back surface of the workpiece conveyed to the press part, wherein the electronic component is not mounted on the back surface; and the cleaning apparatus is arranged at a position overlapping a conveyance path of the workpiece on the upstream side of the press part.

Accordingly, because particles (dust) can be removed by cleaning the back surface of the workpiece before the workpiece is carried into the mold die, it is possible to prevent the workpiece from being carried into the mold die in a state where the particles are adhered to the workpiece.

Further, according to an exemplary embodiment of the present invention, a preheat part that preheats the workpiece is included, and the cleaning apparatus is arranged immediately in front of the preheat part. Accordingly, because cleaning can be performed before a part of particles (for example, the resin powder, or the granular resin which is foreign matter) is hardened by preheating (heating in advance), the particles can be removed more easily.

Further, according to an exemplary embodiment of the present invention, a preheat part that preheats the workpiece is included, and the cleaning apparatus is arranged between the preheat part and the press part. Accordingly, it is possible to prevent the particles from being carried into the press part together with the workpiece to improve molding quality.

Further, according to an exemplary embodiment of the present invention, the cleaning apparatus includes a cleaning head body having: a brush body in which brush bristles come into contact with the back surface of the workpiece; and a suction part that sucks dust. Accordingly, the particles adhered to the back surface of the workpiece can be scraped off by the brush body, and sucked by the suction part to be removed.

Further, according to an exemplary embodiment of the present invention, the cleaning head body includes an actuator that drives the brush bristles to come into contact with or be separated from the back surface of the workpiece. Accordingly, it is possible to adjust the position of the cleaning head body and appropriately press the brush bristles against the workpiece to more reliably perform brushing.

According to an exemplary embodiment of the present invention, the brush body is divided into a plurality of parts in a direction perpendicular to the conveyance direction of the workpiece, and a drive apparatus is included that is individually connected to each of the divided brush bodies and individually drives the brush body up and down. Accordingly, the height position of each of the divided brush bodies can be individually adjusted, and the entire region of the front end of the brush body (brush bristles) can be reliably brought into contact with the workpiece. As a result, the contact area of the brush bristles can be maintained wide and brushing can be performed more reliably.

Further, as another aspect of the present invention, a resin molding apparatus according to the present invention, in which a workpiece with an electronic component mounted on a carrier and a mold resin are carried into a mold die, includes: a press part having the mold die for clamping and resin-sealing the workpiece and the mold resin; and a cleaning apparatus for sucking a front surface of the workpiece conveyed to the press part, wherein the electronic component is mounted on the front surface; and the cleaning apparatus is arranged at a position overlapping a conveyance path of the workpiece on the upstream side of the press part.

Accordingly, because particles (dust) can be removed by cleaning the front surface of the workpiece before the workpiece is carried into the mold die, it is possible to prevent the workpiece from being carried into the mold die in a state where the particles are adhered to the workpiece.

Further, according to an exemplary embodiment of the present invention, the cleaning apparatus is arranged at a position after the mold resin is supplied to the workpiece, and has a suction part that sucks dust. Accordingly, the particles adhered to the front surface of the workpiece due to the soaring of the resin powder or the like when the mold resin is supplied can be removed by the suction part.

Further, as another aspect of the present invention, a resin molding apparatus according to the present invention includes a mold die for compressing and molding a workpiece with an electronic component mounted on a carrier and a mold resin, and the workpiece and the mold resin are separately carried into the mold die; wherein a cleaning apparatus is included at a position after the mold resin is supplied to a resin mold conveying tool that carries the mold resin into the mold die, and the cleaning apparatus has a suction part that sucks dust floating in the resin molding apparatus.

Accordingly, the particles (dust) floating due to the soaring of the resin powder or the like when the mold resin is supplied can be sucked by the suction part. Thus, it is possible to prevent the particles from diffusing in the resin molding apparatus. As a result, deterioration of molding quality (for example, variation in contamination or TTV) can be prevented.

Further, a cleaning method according to the present invention is a cleaning method of a workpiece with an electronic component mounted on a carrier, wherein a cleaning apparatus that comes into contact with the workpiece is arranged at a position overlapping a conveyance path of the workpiece, and the workpiece and the cleaning apparatus are relatively moved to clean a back surface of the workpiece on which the electronic component is not mounted.

Accordingly, it is possible to perform cleaning in the conveyance path of the workpiece to remove the particles (dust) before the workpiece is carried into the mold die. Thus, it is possible to prevent the workpiece from being carried into the mold die in a state where the particles are adhered to the workpiece. In addition, according to an exemplary embodiment of the present invention, brush bristles and a suction part are arranged in the cleaning apparatus.

According to the present invention, it is possible to prevent a workpiece from being carried into a mold die in a state where particles (dust) are adhered to the workpiece. Thus, deterioration of molding quality can be prevented.

### Resin Molding Apparatus

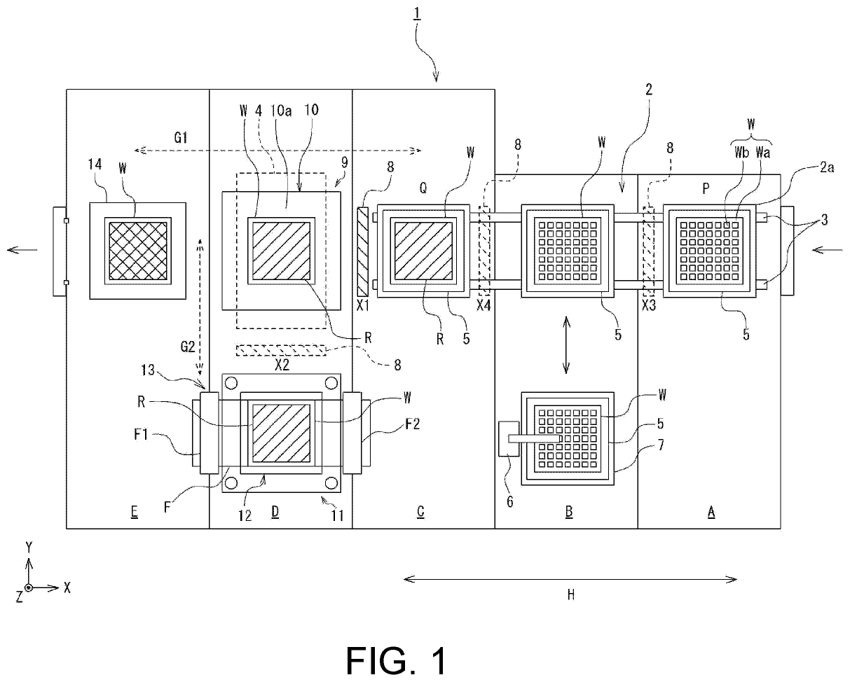

Hereinafter, embodiments of the present invention are described in detail with reference to drawings. FIG. 1 is a schematic diagram showing a configuration example of a resin molding apparatus 1 according to the embodiment of the present invention. In addition, in all the drawings for explaining each embodiment, members having the same function may be designated by the same reference numerals, and the repeated description thereof may be omitted.

The resin molding apparatus 1 according to the embodiment is an apparatus that uses a mold die 12 including an upper die and a lower die to perform resin molding of a workpiece W. Hereinafter, as the resin molding apparatus 1, a compression molding apparatus having a movable cavity in the upper die is described as an example.

First, as an example of the workpiece W to be molded, a workpiece on which an electronic component Wb such as a semiconductor chip or the like is held on a carrier Wa is used. As a main example, a rectangular plate which is 500 mm to 600 mm square in size is used as the carrier Wa. When the carrier Wa is made of metal (copper alloy, stainless alloy, and the like), the carrier Wa is formed as thin as about 0.2 mm in thickness, and when the carrier Wa is made of glass, the carrier Wa is formed as thin as about 1.2 mm in thickness. A plurality of semiconductor chips Wb are attached in a matrix shape onto this carrier Wa by using an adhesive or the like to form the workpiece W. In addition, the workpiece W is not limited to the above configuration. For example, the carrier Wa may have a circular shape. Further, the carrier Wa may be a plate having a maximum width (one side or diameter) of about 400 mm to 700 mm and a thickness of about 0.2 mm to 3 mm. The material of the carrier Wa is also not limited to the above material. In the embodiment, the plate and the semiconductor chip are given as an example of the carrier Wa and the electronic component Wb, but various other configurations may also be adopted.

On the other hand, a mold resin R may be, for example, a thermosetting resin (for example, an epoxy resin containing a filler), and the state of the mold resin R may be granular, powdery, liquid, sheet-like, or in some cases, solid-like typified by a mini-tablet.

Subsequently, the outline of the resin molding apparatus 1 according to the embodiment is described. As shown in FIG. 1, in the resin molding apparatus 1, a workpiece supply unit A, a resin supply unit B, a workpiece delivery unit C, a press unit D, and a cooling unit E are respectively connected in series. In addition, the workpiece W is conveyed by a workpiece conveyance part 2, a loader 4, and the like. Hereinafter, the case of a rectangular workpiece W is described as an example.

A receiving position P (first position) at which the workpiece W is received from a previous process is arranged in the workpiece supply unit A. Further, a delivery position Q (second position) at which the workpiece W is delivered to the loader 4 is arranged in the workpiece delivery unit C. Here, the workpiece conveyance part 2 is configured in a manner that a conveyance part body 2a reciprocates between the receiving position P and the delivery position Q along a rail part 3 arranged among the workpiece supply unit A, the resin supply unit B, and the workpiece delivery unit C (see a solid arrow H in FIG. 1). As an example, the conveyance part body 2a is connected to, for example, a drive belt (not shown) and reciprocates. Further, a holder plate 5 having a rectangular (or grid-like) plate surface which is larger in outer shape and thicker in thickness (for example, about 10 mm) than the workpiece W is arranged on the conveyance part body 2a. With the configuration of the workpiece conveyance part 2, the workpiece W is conveyed in a state of being positioned and placed on the holder plate 5. Thus, even when a workpiece W that is thinner and larger than the conventional one is used, because the workpiece W is conveyed in a state of being placed on the holder plate 5, it is possible to prevent the workpiece W from bending.

Next, a dispenser 6 that supplies the mold resin R (as an example, a granular resin) and a resin supply stage 7 are arranged in the resin supply unit B. While the workpiece W is in a state of being placed on the holder plate 5, a pick-and-place mechanism (not shown) that can move in a Y-Z direction is used to, for example, transfer the workpiece W from the conveyance part body 2a to the resin supply stage 7. The mold resin R is supplied onto the workpiece W from the dispenser 6 while the workpiece W is in a state of being placed on the resin supply stage 7. Here, the dispenser 6 is arranged to be capable of scanning in an X-Y direction on the workpiece W. Further, instead of the dispenser 6, the resin supply stage 7 may be arranged to be capable of scanning in the X-Y direction. Further, an electronic balance (not shown) is arranged on the resin supply stage 7, and the mold resin R supplied onto the workpiece W is weighed so as to have an appropriate amount.

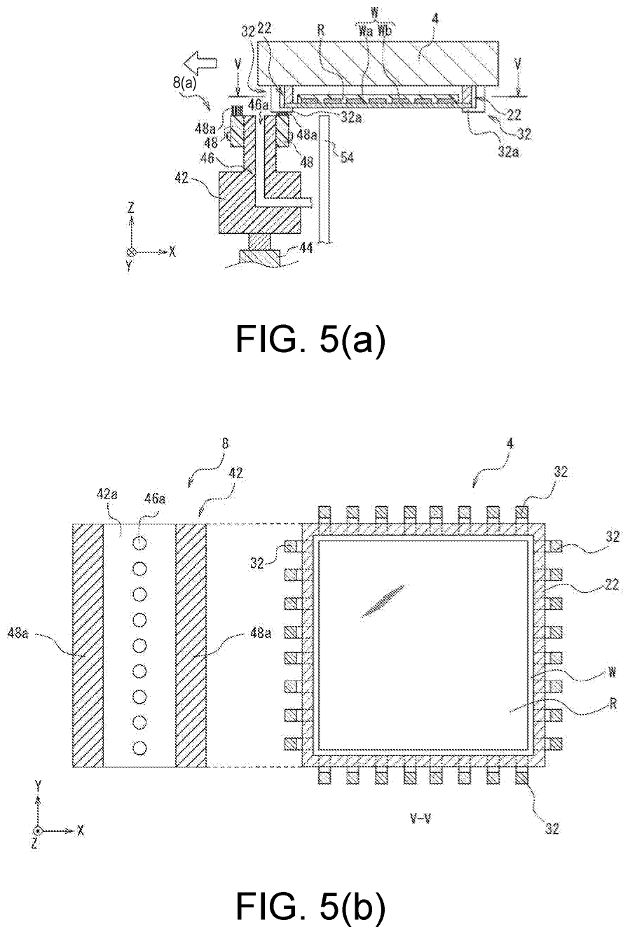

Next, the delivery position Q, serving as a position where the workpiece W which has been supplied with the mold resin R is delivered from the holder plate 5 to the loader 4, is arranged in the workpiece delivery unit C. A mechanism for holding the workpiece W is arranged on the loader 4. Specifically, the loader 4 includes a frame body 22 that is in contact with and separated from an outer edge part on the upper surface of the workpiece W (here, a mounting surface of the electronic component Wb), and a chuck 32 that is in contact with and separated from an outer edge part on the lower surface of the workpiece W (here, a non-mounting surface of the electronic component Wb). The frame body 22 and the chuck 32 are configured to be moved by a moving apparatus (not shown) so that the workpiece W can be held in a vertical direction. As for the loader 4, FIG. 5(a) shows a front cross-section view, and FIG. 5(b) shows a plan cross-section view. In addition, in the front cross-section view, the chuck 32 on the back side is not shown in order to facilitate the understanding of the drawing. With the configuration of the loader 4, the workpiece W is held at the delivery position Q and conveyed in air to a preheat part 9 of the press unit D. The movement range of the loader 4 in the X-Y direction is shown by dashed line arrows G1, G2 in FIG. 1. Further, because the chuck 32 (chuck claw 32a) is configured to be close to but not in contact with the lateral outer peripheral part of the workpiece W by the moving apparatus (not shown), the loader 4 can correct the position where the workpiece W is held.

Further, a cleaning apparatus 8 (details are described later) for removing particles (dust such as resin powder, foreign matter, and the like) adhered to a predetermined surface of the workpiece W is arranged in the workpiece delivery unit C (position of X1). Accordingly, the workpiece W held by the loader 4 can be cleaned, and it is possible to prevent the workpiece W from being carried into the press unit D (the preheat part 9 and press part 11) in a state where the particles are adhered to the workpiece W. In addition, the position where the cleaning apparatus 8 is arranged is not limited to the position of X1. For example, as positions (positions of X2 to X4) shown by dashed lines in FIG. 1, the cleaning apparatus 8 may be arranged at a predetermined position before the workpiece W is carried into the press part 11 (the mold die 12) of the press unit D. Further, the cleaning apparatus 8 may be arranged at a plurality of positions.

Next, the preheat part 9 and the press part 11 are arranged in the press unit D. A preheater 10 is arranged in the preheat part 9. The preheater 10 preheats (heats in advance) the workpiece W which has been supplied with the mold resin R to a predetermined temperature (as an example, about 100° C.) in a state where the workpiece W is placed on a preheat stage 10a. The workpiece W preheated to a predetermined temperature by the preheat part 9 (the preheater 10) is held by the loader 4 and carried into the press part 11(the mold die 12).

On the other hand, the mold die 12 having an upper die and a lower die is arranged in the press part 11. In the embodiment, the mold die 12 has a configuration in which a placement part of the workpiece W is arranged in the lower die, and a movable cavity is arranged in the upper die. After the workpiece W with the mold resin R mounted is carried into the mold die 12 configured in this way, the die is closed and heated to, for example, 130° C. to 150° C. to perform resin molding (compression molding). In addition, as an example, in a die opening/closing mechanism, the lower die is a movable type and the upper die is a fixed type, but the present invention is not limited hereto; the lower die may be a fixed type and the upper die may be a movable type, or both the lower die and the upper die may be movable types. Further, the mold die 12 is opened and closed by a known die opening/closing mechanism (not shown). As an example of the die opening/closing mechanism, a configuration is known to include a pair of platens, a plurality of connection mechanisms (tie bars and pillar parts) on which the pair of platens are erected, and a drive source (for example, an electric motor) and a drive transmission mechanism (for example, a toggle link) that can move (elevate/lower) the platens (none is shown).

Further, a film conveyance mechanism 13 that supplies (conveys) a release film F to the mold die 12 (here, the upper die) is arranged in the press part 11. The press part 11 is configured in a manner that the film conveyance mechanism 13 is included and the release film F is adsorbed and held on the clamp surface of the upper die having the cavity. Here, as the release film F, a long continuous film material having excellent heat resistance, ease of peeling, flexibility, and extensibility is used. For example, polytetrafluoroethylene (PTFE), polytetrafluoroethylene polymer (ETFE), PET, FEP, fluorine-impregnated glass cloth, polypropylene, polyvinylidene chloride, and the like may be used. The release film F is supplied (conveyed) in a manner of being fed from a feeding roll F1, and wound on a winding roll F2 via the clamp surface of the upper die. In addition, instead of the long film, a strip-shaped film cut to a required size corresponding to the workpiece W may be used.

Next, a cooling stage 14 for cooling the workpiece W taken out from the mold die 12 is arranged in the cooling unit E. As an operation example, when a resin mold operation is completed and the mold die 12 is opened, the loader 4 enters the mold die 12 to hold and take out the workpiece W. The workpiece W is conveyed from the press unit D to the cooling unit E while being held by the loader 4, and is delivered to the cooling stage 14 and cooled. In addition, the cooled workpiece W is conveyed to a subsequent process (dicing process and the like).

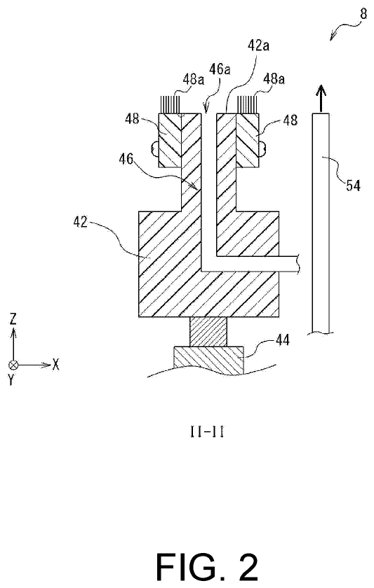

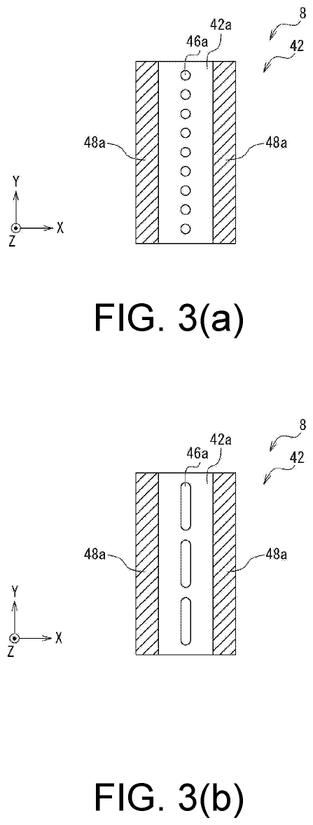

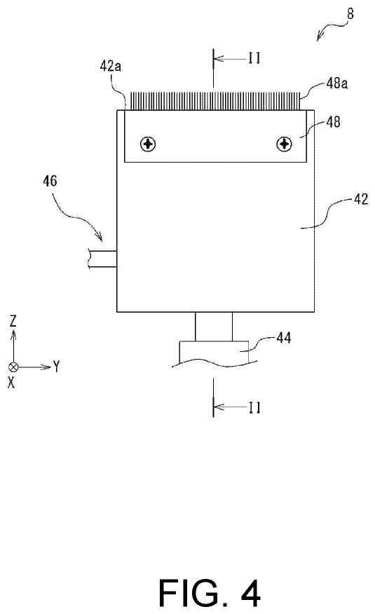

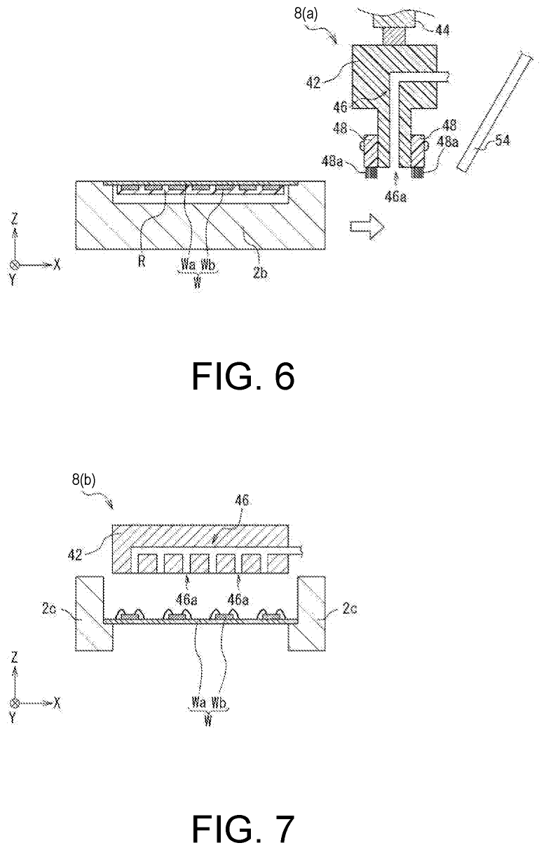

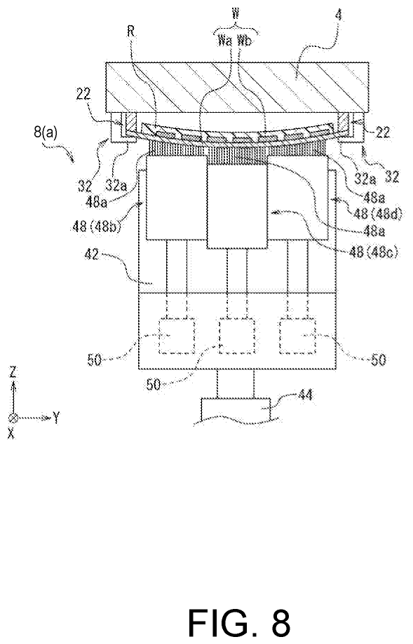

Subsequently, the configuration of the cleaning apparatus 8 according to the embodiment is described in detail. FIG. 2 is a front cross-section view (a cross-section view taken along II-II line of FIG. 4) showing a configuration example of the cleaning apparatus 8 according to the embodiment. FIG. 3(a) and FIG. 3(b) are plan views showing the configuration example of the cleaning apparatus 8 according to the embodiment. FIG. 3(a) and FIG. 3(b) show different configuration examples for a suction port 46a respectively. FIG. 4 is a side view (left side view) showing the configuration example of the cleaning apparatus 8 according to the embodiment. FIG. 5(a) and FIG. 5(b) are explanatory diagrams showing an example in which the cleaning apparatus 8 according to the embodiment is applied to clean a back surface of the workpiece W on which the electronic component Wb is not mounted in the compression molding apparatus having a movable cavity in an upper die. FIG. 6 is explanatory diagram showing an example in which the cleaning apparatus 8 according to the embodiment is applied to the compression molding apparatus having a movable cavity in a lower die. FIG. 7 is an explanatory diagram showing an example in which the cleaning apparatus 8 according to the embodiment is applied to clean a front surface of the workpiece W on which the electronic component Wb is mounted. FIG. 8 is an explanatory diagram showing another example of a brush body 48 of the cleaning apparatus 8 according to the embodiment.

The cleaning apparatus 8 according to the embodiment is an apparatus for removing the particles (dust such as resin powder, foreign matter, and the like) adhered to the predetermined surface of the workpiece W (cleaning the predetermined surface of the workpiece W). The cleaning apparatus 8 according to the embodiment is arranged at a position overlapping the conveyance path of the workpiece W on the upstream side of the press part 11. Hereinafter, first, a cleaning apparatus 8 that is arranged in the workpiece delivery unit C (position of X1) and cleans the back surface of the workpiece W on which the electronic component Wb is not mounted is described as an example.

As shown in FIG. 2, the cleaning apparatus 8 according to the embodiment includes a cleaning head body 42 which is formed into a block shape to stand in the Z direction, for example, with the Y direction as a longitudinal direction and the X direction as a short direction. In addition, the cleaning head body 42 is not necessarily limited to the above-described form. Furthermore, the cleaning head body 42 is not limited to be elongated with respect to the workpiece W, and the cleaning head body 42 may have substantially the same shape (square type) as the workpiece W.

A static elimination blower 54 for blowing ion wind onto the lower surface of the workpiece W (here, the back surface which is the non-mounting surface of the electronic component Wb) is arranged in the vicinity of the cleaning head body 42. As an example, the static elimination blower 54 includes a known ionizer, and removes static electricity by blowing ion air onto the lower surface of the workpiece W so that the particles are made difficult to adhere and easy to remove.

Similarly, an air blower (not shown) for blowing air onto the lower surface of the workpiece W may be arranged in the vicinity of the cleaning head body 42. As an example, a pipe connected to the blower is included, and the particles are blown off and removed by blowing air.

Further, the suction port 46a is arranged at the center in the short direction (X direction) on an upper end surface 42a of the cleaning head body 42. A suction part 46 having a pipe path continuous to the suction port 46a is arranged inside the cleaning head body 42. The suction part 46 is connected to a dust collector (not shown) and sucks air from the suction port 46a. As shown in FIG. 3(a) and FIG. 3(b), the suction parts 46 including the suction ports 46a are arranged at a plurality of locations in the longitudinal direction (Y direction) of the cleaning head body 42.

The suction port 46a is configured by, for example, a small hole shown in FIG. 3(a), a long hole shown in FIG. 3(b), and the like. The shape, size (diameter, length, width, area), number and density of the hole may be appropriately set. For example, when the resin molding apparatus 1 according to the embodiment is configured to supply the mold resin R being granular, the size of the hole (for example, the diameter of the small hole or the short width of the long hole) may be formed larger (for example, about 3 mm) than the maximum diameter of the granule (for example, 2.5 mm). Accordingly, the granular resin which is foreign matter adhered to a surface of the workpiece W on which the mold resin R is not supplied can be sucked from the suction port 46a. In addition, the operation of the dust collector is controlled by a control part (not shown).

Further, a pair of brush bodies 48 are individually screwed and fixed to the upper end part of the cleaning head body 42 on both surfaces in the short direction (X direction). The brush body 48 extends along the longitudinal direction (Y direction) of the cleaning head body 42, and brush bristles 48a are planted at the upper end part. As shown in FIG. 3(a) and FIG. 3(b), on the upper end surface 42a of the cleaning head body 42, the suction port 46a is surrounded by the pair of brush bristles 48a standing on both sides in the short direction (X direction) in a plan view. In addition, the brush body 48 and the brush bristles 48a may be arranged on only one side of the upper end surface 42a of the cleaning head body 42 where the suction port 46a is sandwiched.

The brush body 48 is arranged to be movable up and down to a predetermined degree by forming a screw hole slightly and loosely in the vertical direction (Z direction). Further, an installing position (here, a position in the Z direction, which is the height position) of the brush body 48 with respect to the cleaning head body 42 can be changed. Further, the brush body 48 may be an integral body, or may be divided into a plurality of parts. When the brush body 48 is divided into a plurality of parts, the installing position can be adjusted in the vertical direction according to the warp of the workpiece W. In addition, as shown in FIG. 2 to FIG. 4, an actuator 44 that makes the height position of the brush bristles 48a (a position in the Z direction) variable is arranged in the cleaning head body 42. As an example, the actuator 44 includes a servo mechanism, and is connected to the lower end part of the cleaning head body 42 to drive the cleaning head body 42 up and down. Further, at least the brush bristles 48a may be formed by a static elimination brush using an electro static discharge (ESD) material. Accordingly, by removing static electricity from the resin which is electrostatically attached to the lower surface of the workpiece W with the static elimination brush, the workpiece W can be antistatic and the resin can be easily peeled off from the workpiece W, and it is possible to prevent the mold resin R (for example, granules) placed on the upper surface of the workpiece W (particularly, the outer edge part near the lower surface) from being adsorbed on the brush bristles 48a which is in contact with the lower surface of the workpiece W.

In addition, a sponge-like adhesive roller (not shown) may be arranged in place of the brush body 48 or together with the brush body 48. The adhesive roller comes into contact with the lower surface of the workpiece W to attach and remove the particles.

Here, as shown in FIG. 1, the cleaning apparatus 8 is arranged at a position overlapping the conveyance path of the workpiece W. Specifically, for example, the cleaning apparatus 8 is arranged at a position (position of X1) immediately in front of the preheat part 9 in a manner that the longitudinal direction (Y direction) of the cleaning head body 42 is orthogonal to the conveyance direction (X direction) of the workpiece W conveyed by the loader 4. In addition, the operation of the air blower and the static elimination blower 54 and the driving of the actuator 44 are controlled by the control part (not shown).

According to the above configuration, because the cleaning apparatus 8 is arranged at a position overlapping the workpiece W on the upstream side of the press part 11 in the conveyance path of the workpiece W, the particles adhered to the lower surface of the workpiece W (here, the back surface which is the non-mounting surface of the electronic component Wb) can be sucked and removed before the workpiece W is carried into the mold die 12. Further, if the cleaning apparatus 8 is arranged at a position immediately in front of the preheat part 9, it is possible to prevent the particles (for example, the resin powder, or the granular resin which is foreign matter) adhered to the lower surface of the workpiece W from being heat-hardened by preheating. Further, while the upper end surface 42a of the cleaning head body 42 is arranged to face the workpiece W conveyed by the loader 4, and the brush bristles 48a planted on the brush body 48 are brought into contact with the lower surface of the workpiece W, the particles scraped off when the loader 4 conveys the workpiece W can be sucked and removed from the suction port 46a. As a result, deterioration of molding quality (for example, variation in contamination or TTV) can be prevented.

Here, for example, as shown in FIG. 5(a), the height position (the position in the Z direction) of the brush body 48 with respect to the cleaning head body 42 may be set as a position where a part of the brush bristles 48a interferes with the chuck claw 32a of the loader 4 moving in the X direction. Accordingly, the loader 4 can proceed without being hindered by the cleaning head body 42, and the brush bristles 48a can be brought into contact with the lower surface of the workpiece W as the loader 4 proceeds.

On the other hand, the cleaning head body 42 may be driven up and down by the actuator 44 that makes the height position (the position in the Z direction) of the brush bristles 48a described above variable, so that the brush bristles 48a may be brought into contact with and separated from the lower surface of the workpiece W a plurality of times when the workpiece W is conveyed. In this case, for example, the chuck claw 32a of the loader 4 is avoided from interfering with the brush bristles 48a, the cleaning head body 42 is appropriately pressed against the workpiece W, and thereby the brushing can be performed more reliably. In addition, a storage part (not shown) for storing product type data (for example, information about the shape, size (diameter, thickness, and the like), material, and the like of the carrier Wa) of the workpiece W may be arranged at a predetermined position of the resin molding apparatus 1. In this case, the control part that controls the driving of the actuator 44 can be adjusted to a predetermined position corresponding to the workpiece W based on the height position (the position in the Z direction) of the brush bristles 48a and the product type data.

Further, the size of the cleaning head body 42 is not limited. For example, as shown in FIG. 5(b), the width in the longitudinal direction (Y direction) orthogonal to the conveyance direction (X direction) of the workpiece W may be set to be equal to or larger than the maximum width of the workpiece W (the carrier Wa). Accordingly, the entire region of the lower surface of the workpiece W can be cleaned.

In addition, as another example, as shown in FIG. 8, because the brush body 48 is divided into a plurality of parts in a direction (Y direction) perpendicular to the conveyance direction (X direction) of the workpiece W, and the installing position (here, the position in the Z direction, which is the height position) of each of the divided brush bodies 48b, 48c, and 48d with respect to the cleaning head body 42 can be individually changed, the brush body 48 (the brush bristles 48a) can be moved up and down more finely. Thus, even if the workpiece W is warped, the entire region of the front end of the brush bristles 48a can be brought into contact with the workpiece W more reliably. As a result, the contact area of the brush bristles 48a can be maintained wide and the brushing can be performed more reliably. The number of the brush body 48 to be divided is not limited, and each brush body 48b, 48c, 48d may not be divided into a uniform size. In addition, as shown in FIG. 8, a moving apparatus 50 that makes the height position (the position in the Z direction) of the divided brush bristles 48a individually variable may be arranged in the cleaning head body 42. As an example, the moving apparatus 50 includes a servo mechanism, and is individually connected to each of the divided brush bodies 48b, 48c, and 48d to individually drive each brush body 48b, 48c, 48d up and down.

Accordingly, even if the workpiece W held by the loader 4 is bent, because the height position of each of the divided brush bodies 48b, 48c, and 48d can be adjusted individually, the entire region of the front end of the brush bristles 48a can be brought into contact with the workpiece W more reliably.

Furthermore, as another example, the cleaning head body 42 may be divided into a plurality of parts in a direction (Y direction) perpendicular to the conveyance direction (X direction) of the workpiece W, and the actuator may be individually connected to each of the divided cleaning head bodies (for example, the lower end part) to individually drive each cleaning head body up and down (not shown). In this case, the brush body 48 arranged in the cleaning head body 42 is also divided into a plurality of parts. Thus, each of the divided brush bodies 48b, 48c, and 48d can also be driven up and down respectively by driving each cleaning head body up and down individually.

Further, the cleaning apparatus 8 may be arranged between the preheat part 9 and the press part 11 (at the position of X2). In this case as well, because the cleaning apparatus 8 is arranged at a position overlapping the workpiece W on the upstream side of the press part 11 in the conveyance path of the workpiece W, the particles adhered to the lower surface of the workpiece W (here, the back surface which is the non-mounting surface of the electronic component Wb) can be sucked and removed before the workpiece W is carried into the mold die 12. Further, if the cleaning apparatus 8 is arranged between the preheat part 9 and the press part 11, there is no reattachment because there is no subsequent conveyance, and it is possible to prevent the particles from being carried into the press part 11 together with the workpiece W and improve the molding quality. In addition, the workpiece W held by the loader 4 is conveyed in the Y direction between the preheat part 9 and the press part 11 (see the dashed line arrow G2 in FIG. 1). Thus, the cleaning apparatus 8 arranged at the position of X1 described above may be rotated 90° in the horizontal direction (regardless of the left and right directions) and installed at the position of X2.

As described above, the cleaning apparatus 8 according to the embodiment may be arranged at a predetermined position before the workpiece W is carried into the press part 11 (the mold die 12) of the press unit D, that is, a position overlapping the workpiece W on the upstream side of the press part 11 (the mold die 12) in the conveyance path of the workpiece. Thereby, it is possible to prevent the workpiece W from being carried into the mold die 12 in a state where the particles are adhered to the workpiece W. Certainly, the cleaning apparatus 8 may be arranged at a plurality of positions (for example, both the position of X1 and the position of X2). In this case, the workpiece W can be cleaned more reliably.

Further, in the above description, the cleaning apparatus 8 according to the embodiment is a cleaning apparatus 8 (hereinafter referred to as a “cleaning apparatus 8a”) for cleaning the back surface of the workpiece W on which the electronic component Wb of the workpiece W is not mounted, and on the other hand, the cleaning apparatus 8 according to the embodiment may be a cleaning apparatus 8 (hereinafter referred to as a “cleaning apparatus 8b”) for cleaning a front surface of the workpiece W on which the electronic component Wb of the workpiece W is mounted. Specifically, the cleaning apparatus 8a is turned upside down to remove the brush body 48 and installed on the upper part of the conveyance path of the workpiece W, and thereby the workpiece W held by the loader 4 passes through the lower part of the cleaning head body 42 (See FIG. 7. In FIG. 7, the workpiece W before the resin is mounted on the semiconductor chip Wb which is wire-connected is conveyed to a conveying rail 2c, but the cleaning head body 42 is the same). Accordingly, the upper surface of the workpiece W (here, the front surface of the workpiece W, which is the mounting surface of the electronic component Wb) can be cleaned. Thus, by arranging the cleaning apparatus 8a at, for example, the positions of X1 and X2 and arranging the cleaning apparatus 8b at positions of X3 and X4, the mounting surface and the non-mounting surface of the electronic component Wb of the carrier Wa sandwiched between a pair of mold dies 12 in the entire resin molding apparatus 1 can be cleaned, and deterioration of molding quality (for example, variation in contamination or TTV) can be prevented. Further, it is possible to prevent the mold die 12 from being adhered by the particles and contaminated by cleaning the mounting surface and the non-mounting surface which may come into direct contact with the mold die 12.

In addition, the mold resin R supplied by the resin supply unit B is placed on the workpiece W at the position of X4. Thus, when the cleaning apparatus 8b is arranged at these positions, it is necessary to configure the cleaning apparatus 8b in a manner that the mold resin R is not sucked by the cleaning apparatus 8b. Specifically, the brush body 48 and the air blower may not arranged. Further, the driving of the suction part 46 may be adjusted appropriately by relatively weakening the suction force or shifting the timing of suction, or the size of the hole of the suction port 46a may be formed to be smaller than the maximum diameter of the mold resin R (for example, the granule) so that only fine particles such as resin powder can be sucked and the mold resin R cannot be sucked.

Specifically, the cleaning apparatus 8b may be arranged at a position before the mold resin R is supplied to the workpiece W. As an example, the cleaning apparatus 8b may be arranged between the workpiece supply unit A and the resin supply unit B (at the position of X3). Accordingly, when the workpiece W held by the conveyance part body 2a is conveyed from the workpiece supply unit A to the resin supply unit B, the cleaning head body 42 can be arranged on the upper part of the conveyance path of the workpiece W to clean the upper surface (here, the supply surface of the mold resin R, which is the front surface of the workpiece W serving as the mounting surface of the electronic component Wb). Thus, it is possible to prevent the workpiece W from being carried into the resin supply unit B (the resin supply stage 7) in a state where the particles are adhered to the workpiece W. As a result, it is possible to prevent the particles from being mixed into the mold resin R when the mold resin R is supplied onto the workpiece W.

On the other hand, the cleaning apparatus 8b may be arranged at a position after the mold resin R is supplied to the workpiece W. As an example, the cleaning apparatus 8b may be arranged between the resin supply unit B and the workpiece delivery unit C (at the position of X4). Accordingly, when the workpiece W held by the conveyance part body 2a is conveyed from the resin supply unit B to the workpiece delivery unit C, the cleaning head body 42 can be arranged on the upper part of the conveyance path of the workpiece W to clean the upper surface (here, the supply surface of the mold resin R, which is the front surface of the workpiece W serving as the mounting surface of the electronic component Wb). Thus, it is possible to remove the particles adhered to the upper surface of the workpiece W due to the soaring of the resin powder or the like when the mold resin R is supplied by the resin supply unit B (on the resin supply stage 7). As a result, it is possible to prevent the workpiece W from being carried into the press unit D (the preheat part 9 and the press part 11) in a state where the particles are adhered to the workpiece W.

In addition, the mold resin R supplied by the resin supply unit B is placed on the workpiece W arranged at the position of X4. Thus, similar to the above description, it is necessary to configure the cleaning apparatus 8b in a manner that the mold resin R on the workpiece W is not sucked.

In this way, similar to the cleaning apparatus 8a for cleaning the back surface of the workpiece W on which the electronic component Wb of the workpiece W is not mounted, the cleaning apparatus 8b for cleaning the front surface of the workpiece W on which the electronic component Wb of the workpiece W is mounted may be appropriately arranged at a predetermined position before the workpiece W is carried into the press part 11 (the mold die 12) of the press unit D, that is, a position overlapping the workpiece W on the upstream side of the press part 11 (the mold die 12) in the conveyance path of the workpiece.

Further, the cleaning apparatus 8 according to the embodiment can also be applied to a compression molding apparatus having a movable cavity in the lower die. That is, at least one of the cleaning apparatus 8a and the cleaning apparatus 8b may be arranged at a position overlapping the workpiece W on the upstream side of the press part 11 in the conveyance path of the workpiece W. For example, as shown in FIG. 6, the cleaning apparatus 8a may be turned upside down and installed on the upper part of the conveyance path of the workpiece W which is held by a conveying tool 2b (for example, a conveying loader) so as to clean the upper surface of the workpiece W (here, the back surface of the workpiece W, which is the non-mounting surface of the electronic component Wb) (in addition, in this example, the conveying tool 2b moves in the X direction).

Further, the cleaning apparatus 8 according to the embodiment can also be applied to a transfer molding apparatus. That is, at least one of the cleaning apparatus 8a and the cleaning apparatus 8b may be arranged at a position overlapping the workpiece W on the upstream side of the press part 11 in the conveyance path of the workpiece W. In this case, the resin is not mounted on the workpiece W before the press part 11, but it is effective because the tablet is chipped and the resin flash after molding scatters. For example, as shown in FIG. 7, the cleaning apparatus 8b may be installed on the upper part of the conveyance path of the workpiece W which is held by a conveying tool 2c (for example, the conveying rail) so as to clean the upper surface of the workpiece W (here, the front surface of the workpiece W, which is the mounting surface of the electronic component Wb) (in addition, in this example, the conveying tool 2c moves in the Y direction).

In this way, even when the cleaning apparatus 8 according to the embodiment is applied to the compression molding apparatus having a movable cavity in the lower die or the transfer molding apparatus, because the workpiece W can be cleaned to remove the particles before the workpiece W is carried into the mold die 12, it is possible to prevent the workpiece W from being carried into the mold die 12 in a state where the particles are adhered to the workpiece W.

Furthermore, regarding the cleaning apparatus 8 according to the embodiment, the resin molding apparatus 1 according to the embodiment may have the following configuration. That is, in a configuration (for example, the compression molding apparatus having a movable cavity in the lower die) in which the mold die 12 for compressing and molding the workpiece W with the electronic component Wb mounted on the carrier Wa and the mold resin R are included, and the workpiece W and the mold resin R are separately carried into the mold die 12, the cleaning apparatus 8 is included at a position after the mold resin R is supplied to a resin mold conveying tool (not shown) that carries the mold resin R into the mold die 12, and the cleaning apparatus 8 has the suction part 46 that sucks the particles (dust) floating in the resin molding apparatus 1.

According to the above configuration, by arranging the cleaning apparatus 8 at a position after the mold resin R is supplied, the particles floating due to the soaring of the resin powder or the like when the mold resin R is supplied can be sucked by the suction part 46. Thus, it is possible to prevent the particles from diffusing in the resin molding apparatus 1. As a result, deterioration of molding quality (for example, variation in contamination or TTV) can be prevented. Further, in the configuration in which the workpiece W is carried into the mold die 12, the cleaning apparatus 8a for cleaning the back surface of the workpiece W, which is the non-mounting surface of the electronic component Wb, is included in the conveyance path of the workpiece W, and thereby it is possible to prevent the particles from being carried into the mold die 12.

### Cleaning Method of Workpiece

In a cleaning method of the workpiece W in which the electronic component Wb is mounted on the carrier Wa according to the embodiment, the cleaning apparatus 8 that comes into contact with the workpiece W is arranged at a position overlapping the conveyance path of the workpiece W, the workpiece W and the cleaning apparatus 8 are relatively moved to clean the back surface of the workpiece on which the electronic component Wb of the workpiece W is not mounted. In the embodiment, the workpiece W and the cleaning apparatus 8 are moved in a manner that the entire region of the target surface of the workpiece W and the cleaning apparatus 8 overlap each other, so that the entire region of the target surface of the workpiece W can be cleaned. At this time, at least one of the workpiece W and the cleaning apparatus 8 may be moved. If the workpiece W is moved, the workpiece conveyance can be used, and the mechanism can be simplified and the manufacturing cost can be reduced. In addition, the brush bristles 48a and the suction part 46 may be arranged as appropriate in the cleaning apparatus 8.

According to the method of the embodiment, it is possible to perform cleaning in the conveyance path of the workpiece W to remove the particles (dust) before the workpiece W is carried into the mold die 12. Thus, it is possible to prevent the workpiece W from being carried into the mold die 12 in a state where the particles are adhered to the workpiece W.

In addition, the present invention is not limited to the examples described above, and various modifications can be made without departing from the present invention. In particular, the configuration in which the plurality of semiconductor chips are mounted in a matrix shape on the rectangular plate to form the workpiece has been described as an example, but the present invention is not limited hereto. For example, a workpiece using other members instead of the plate as a mounted member, a workpiece using other electronic components or elements instead of the semiconductor chip as a mounting member, or other workpieces may also be used to perform resin molding in the same manner. Further, the larger the workpiece, the more likely it is to bend, but the configuration of the present invention can also be applied to a workpiece having a normal size, such as a so-called resin substrate or lead frame strip substrate of 100×300 mm or less even if this workpiece is not a large workpiece of 500 mm on one side.

What is claimed is:

1. A resin molding apparatus,
in which a workpiece with an electronic component mounted on a carrier and a mold resin are carried into a mold die, comprising:
a press part having the mold die for clamping and resin-sealing the workpiece and the mold resin; and
a cleaning apparatus for cleaning a back surface of the workpiece conveyed to the press part, wherein the electronic component is not mounted on the back surface;
wherein the cleaning apparatus is arranged at a position overlapping a conveyance path of the workpiece on an upstream side of the press part.

2. The resin molding apparatus according to claim 1, comprising
a preheat part that preheats the workpiece,
wherein the cleaning apparatus is arranged immediately in front of the preheat part.

3. The resin molding apparatus according to claim 1, comprising
a preheat part that preheats the workpiece,
wherein the cleaning apparatus is arranged between the preheat part and the press part.

4. The resin molding apparatus according to claim 1,
wherein the cleaning apparatus comprises a cleaning head body having: a brush body in which brush bristles come into contact with the back surface of the workpiece; and a suction part that sucks dust.

5. The resin molding apparatus according to claim 4,
wherein the cleaning head body comprises an actuator that drives the brush bristles to come into contact with or be separated from the back surface of the workpiece.

6. The resin molding apparatus according to claim 4,
wherein the brush body is divided into a plurality of parts in a direction perpendicular to the conveyance direction of the workpiece, and
the resin molding apparatus comprises a drive apparatus that is individually connected to each of the divided brush bodies and individually drives the brush body up and down.

7. A resin molding apparatus,
in which a workpiece with an electronic component mounted on a carrier and a mold resin are carried into a mold die, comprising:
a press part having the mold die for clamping and resin-sealing the workpiece and the mold resin; and
a cleaning apparatus for sucking a front surface of the workpiece conveyed to the press part, wherein the electronic component is mounted on the front surface,
wherein the cleaning apparatus is arranged at a position overlapping a conveyance path of the workpiece on an upstream side of the press part.

8. The resin molding apparatus according to claim 7,
wherein the cleaning apparatus is arranged at a position after the mold resin is supplied to the workpiece, and has a suction part that sucks dust.

9. A resin molding apparatus,
which comprises a mold die for compressing and molding a workpiece with an electronic component mounted on a carrier and a mold resin, and in which the workpiece and the mold resin are separately carried into the mold die,
wherein a cleaning apparatus is arranged at a position after the mold resin is supplied to a resin mold conveying tool that carries the mold resin into the mold die, and
the cleaning apparatus has a suction part that sucks dust floating in the resin molding apparatus.

10. A cleaning method,
which is a cleaning method of a workpiece with an electronic component mounted on a carrier,
wherein a cleaning apparatus that comes into contact with the workpiece is arranged at a position overlapping a conveyance path of the workpiece, and the workpiece and the cleaning apparatus are relatively moved to clean a back surface of the workpiece on which the electronic component is not mounted.

11. The cleaning method according to claim 10,
wherein brush bristles and a suction part are arranged in the cleaning apparatus.
